(19) United States
(12) Patent Application Publication
(10) Pub. No.: US 2011/0120557 A1
(43) Pub. Date: May 26, 2011

(54) MANUFACTURING METHOD FOR THIN FILM TYPE LIGHT ABSORBING LAYER, MANUFACTURING METHOD FOR THIN FILM SOLAR CELL USING THEREOF AND THIN FILM SOLAR CELL

(75) Inventors: Jeongdae SUH, Daejeon (KR); Kibong Song, Daejeon (KR); Changwoo Ham, Daejeon (KR); Myungae Chung, Daejeon (KR); Sungwon Sohn, Daejeon (KR)

(73) Assignee: Electronics and Telecommunications Research Institute, Daejeon (KR)

(21) Appl. No.: 12/817,062

(22) Filed: Jun. 16, 2010

(30) Foreign Application Priority Data
Nov. 20, 2009 (KR) 10-2009-0112414

(51) Int. Cl. H01L 31/032; H01L 31/18

(52) U.S. Cl. 136/262; 438/95; 257/E31.027

(57) ABSTRACT

Disclosed is a manufacturing method for a thin film type light absorbing layer of a solar cell. The manufacturing method for a light absorbing layer includes: filling CIGS crystal powder in an evaporation source of a chamber; simultaneously evaporating the CIGS crystal powder; and depositing the evaporated CIGS crystal powder on a substrate to form a CIGS thin film.

### RELATED APPLICATIONS

The present application claims priority to Korean Patent Application Serial Number 10-2009-0112414, filed on Nov. 20, 2009, the entirety of which is hereby incorporated by reference.

### BACKGROUND OF THE INVENTION

1. Field of the Invention

The embodiment relates to a thin film solar cell, and more specifically, to a manufacturing method for a thin film type light absorbing layer formed by CIGS crystal powder, a manufacturing method for a thin film solar cell using thereof, and a thin film solar cell manufactured by the manufacturing method.

2. Description of the Related Art

A solar cell technology has recently been interested as an eco-friendly new renewable energy technology, specifically, as an energy source for commercial power production and portable or mobile electronic devices.

A solar cell is provided with a light absorbing layer for absorbing light, wherein the light absorbing layer is manufactured in a thin film type.

The thin film type light absorbing layer uses a CIGS thin film having a composition of copper (Cu), indium (In), gallium (Ga), and selenium (Se) in order to increase the photoelectric absorption conversion efficiency of the solar cell. This is because the CIGS has a high light absorption coefficient and a wide bandgap, which exhibits optically high stability and high photoelectric absorption conversion efficiency.

The light absorbing layer using the CIGS thin film in the related art is formed by being deposited on a glass substrate using a deposition method that is based on vacuum deposition, for example, a vaporizing deposition method, a sputtering deposition method, etc.

However, when the light absorbing layer is formed by the vaporizing deposition method according to the related art, it is difficult to accurately control an evaporation temperature or an evaporation speed due to having different vaporizing temperatures of each evaporation material and it is difficult to control a composition of the CIGS light absorbing layer due to a phenomenon of when the evaporation materials bounce from an evaporation source.

In addition, when the light absorbing layer is formed by the sputtering deposition method according to the related art, it is difficult to control a composition ratio of each element of the CIGS and further, the sputtering using the anion of selenium impacts the light absorbing layer such that the light absorbing layer has many defects.

Therefore, the manufacturing method for a light absorbing layer in the related art requires a long manufacturing process and complication process, thereby making it difficult to control the composition.

### SUMMARY OF THE INVENTION

Therefore, it is an object of the present invention to provide a manufacturing method for a thin film type light absorbing layer that can rapidly and simply manufacture a high-quality CIGS light absorbing layer.

It is another object of the present invention to provide a manufacturing method for a thin film solar cell using a manufacturing method for a thin film type light absorbing layer.

It is yet another object of the present invention to provide a thin film solar cell including a thin film type light absorbing layer.

In order to solve the above problems, a manufacturing method for a thin film type light absorbing layer according to one embodiment of the present invention includes: filling CIGS crystal powder in an evaporation source of a chamber; simultaneously evaporating the CIGS crystal powder; and depositing the evaporated CIGS crystal powder on a substrate to form the CIGS thin film.

The manufacturing method for a thin film type light absorbing layer further includes performing a selenization process on the CIGS thin film for forming the CIGS thin film and then evaporating selenium metal powder.

The CIGS crystal powder has a diameter of 10 nm to 2 μm and the composition ratio of copper:indium:gallium:selenium of 1:(1−x):x:y, where x represents a real number of more than 0 to less than 1 and y represents a real number of 1 to 3.

The CIGS thin film is formed on the substrate at a thickness of 100 nm to 3 μm.

The simultaneously evaporating the CIGS crystal powder includes heating the substrate while maintaining the chamber in a vacuum state and evaporating the CIGS crystal powder by heating the evaporation source. The evaporation source is heated in the range of 1000 to 1400° C.

The manufacturing method for a thin film type light absorbing layer further includes an electrode layer on the substrate prior to forming the CIGS thin film, wherein the CIGS thin film is formed on the electrode layer.

In order to solve the above problems in the related art, a manufacturing method for a thin film solar cell according to one embodiment of the present invention includes: forming a back electrode layer on one surface of the substrate; forming a thin film type light absorbing layer by evaporating and depositing CIGS crystal powder on the rear electrode layer; forming a buffer layer on a thin film type light absorbing layer; and forming a window layer on the buffer layer.

The manufacturing method for a thin film solar cell further includes forming an anti-reflective layer on the window layer.

The manufacturing method for a thin film solar cell further includes forming a front electrode layer on the window layer.

In order to solve the above problems in the related art, a thin film solar cell according to one embodiment of the present invention includes a back electrode layer that is formed on one surface of a substrate; a thin film type light absorbing layer that is formed by evaporating and depositing the CIGS crystal powder on the back electrode layer; a buffer layer that is formed on the thin film type light absorbing layer, and a window layer that is formed on the buffer layer.

According to the manufacturing method for a thin film type light absorbing layer, the manufacturing method for a thin film solar cell using thereof, and a thin film solar cell, the light absorbing layer is formed by a thermal evaporation deposition method using the CIGS crystal powder, thereby making it possible to form a high-quality CIGS thin film type light absorbing layer.

In addition, the CIGS crystal powder are simultaneously evaporated, thereby making it possible to reduce the amount of time in the manufacturing process of the thin film type light absorbing layer, increase the process efficiency, and manufacture the high-quality CIGS thin film type light absorbing layer and CIGS thin film solar cell at low cost.

### BRIEF DESCRIPTION OF THE DRAWINGS

A brief description of each drawing is provided in order to more fully understand the drawings cited in the detailed description of the present invention:

FIG. 1 is a process flow chart that forms a thin film type light absorbing layer of a thin film solar cell according to one embodiment of the present invention;

FIG. 2 is a schematic configuration diagram of an apparatus for forming a thin film type light absorbing layer;

FIG. 3 is a process flow chart of a manufacturing method for a thin film solar cell according to one embodiment of the present invention;

FIGS. 4A to 4F are diagrams according to the process flow chart of FIG. 3;

FIG. 5 is a graph for analyzing an X ray crystal structure of a CIGS crystal powder that forms a thin film type light absorbing layer;

FIGS. 6A and 6B are pictures of crystal particles of CIGS crystal powder taken by electron microscope;

FIG. 7 is a graph for analyzing an X ray crystal structure of the thin film type light absorbing layer;

FIG. 8 is a picture of surface of the thin film type light absorbing layer taken by electron microscope; and

FIG. 9 is a picture of cross section of the thin film type light absorbing layer taken by electron microscope.

### DETAILED DESCRIPTION OF THE PREFERRED EMBODIMENTS

In order to fully understand the benefits in the operation of the present invention and objects to be achieved by exemplary embodiments of the present invention, the accompanying drawings illustrating the exemplary embodiments of the present invention and the contents described in the accompanying drawings should be referred.

Hereinafter, the exemplary embodiment of the present invention will be described in detail with reference to the accompanying drawings to help understand the present invention. Like reference numerals proposed in each drawing denote like components.

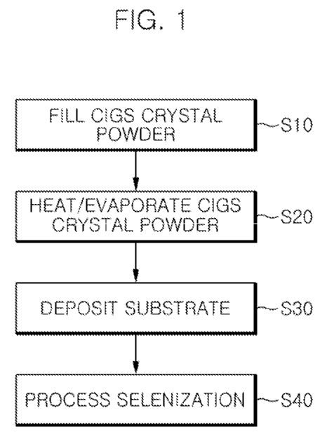

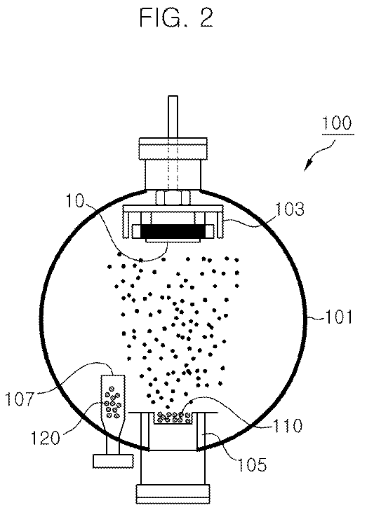

FIG. 1 is a process flow chart that forms a thin film type light absorbing layer of a thin film solar cell according to one embodiment of the present invention and FIG. 2 is a schematic configuration diagram of an apparatus for forming a thin film type light absorbing layer.

Referring to FIGS. 1 and 2, an apparatus 100 for manufacturing a thin film type light absorbing layer may include a chamber 101, a first evaporation source 105, a second evaporation source 107, and a substrate fixing part 103.

The inside of the chamber 101 may be maintained in a vacuum state. Although not shown in detail in FIG. 1, the chamber 101 can further include a vacuum pump (not shown) for maintaining a vacuum state. The vacuum pump may maintain the inside of the chamber 101 in a vacuum state of approximately 10⁻⁶ Torr or less.

The substrate fixing part 103 may fix the substrate 10 so that a surface, on which the thin film type light absorbing layer is formed, is positioned at the lower part thereof. In other words, the substrate fixing part 103 may fix the substrate 10 so that a first evaporation source 105, which is filled with copper (Cu)-indium (In)-gallium (Ga)-selenium (Se) (hereinafter, CIGS) crystal powder 110 faces one surface of the substrate 10, that is, one surface on which the thin film type light absorbing layer is formed.

Meanwhile, although not shown in detail in FIG. 1, the substrate fixing part 103 may further include a heater (not shown) that can heat the substrate 10.

The heater may heat the substrate 10 fixed to the substrate fixing part 103 so that the substrate 10 is maintained at approximately 300 to 650° C.

The first evaporation source 105 may be positioned facing the substrate fixing part 103 and filled with the CIGS crystal powder 110 and evaporates them.

The first evaporation source 105 may be made of molybdenum (Mo), tungsten; etc., and heated at approximately 1000 to 1400° C., thereby making it possible to evaporate the CIGS crystal powder 110.

The second evaporation source 107 may be filled with selenium metal powder 120 for performing a selenization process on the substrate 10 and evaporates them. The second evaporation source 107 is heated to approximately 100 to 200° C., thereby making it possible to evaporate the selenium metal powder 120.

First, in order to form the thin film type light absorbing layer, the substrate 10 is fixed to the substrate fixing part 103 of the chamber 101.

The substrate 10 may be one of a soda ash glass substrate, a stainless metal substrate, and a polyimide polymer substrate.

According to another embodiment of the present invention, an electrode layer of molybdenum is deposited on one surface of the substrate 10 and the electrode layer may be fixed to face the first evaporation source 105.

After the substrate 10 is fixed to the substrate fixing part 103, the CIGS crystal powder 100 may be filled in the first evaporation source 105 (S10).

The CIGS crystal powder 110 may have a chalcopyrite crystal structure and since the crystal powder inherently has a pure CIGS structure, it can easily control the composition of the thin film type light absorbing layer while maintaining high homogeneity.

In addition, the CIGS crystal powder 110 may have a composition ratio of copper:indium:gallium:selenium of 1:(1−x):x:y where x and y are represent a real numbers and x is represents 0<x<1 and y is represents 1≦y≦3.

In the present embodiment, the CIGS crystal powder 110 may have a composition ratio of copper:indium:gallium:selenium of 1:(0.8 to 0.9):(0.1 to 0.4):(1.8 to 3) as one example.

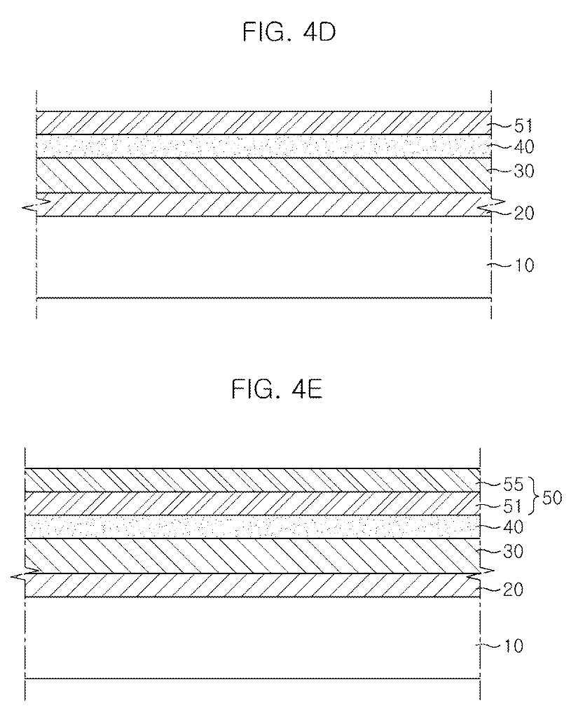

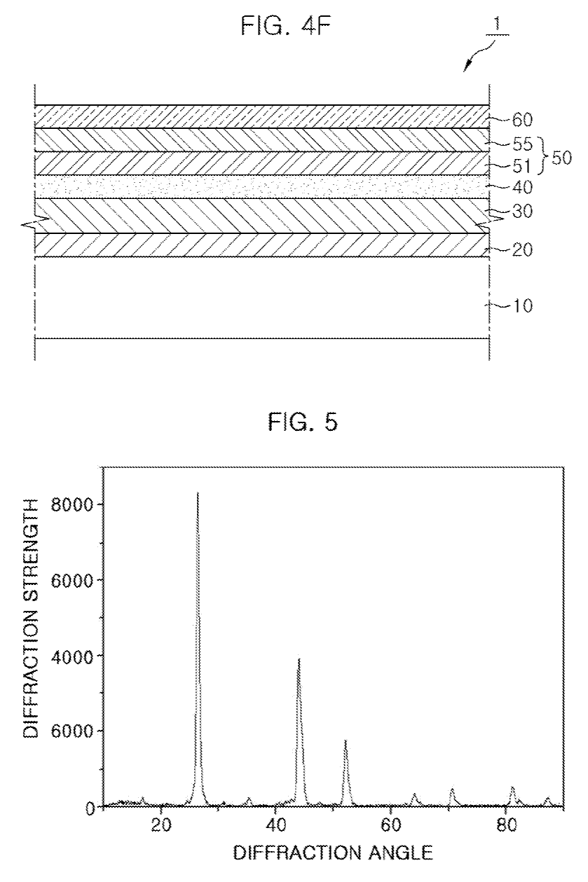

As shown in FIGS. 5 and 6, the CIGS crystal powder may have a crystal particle diameter of several tens of nano (nm) to several micro (μm). For example, in the present embodiment, the CIGS crystal powder 100 may have a crystal particle diameter of 10 nm to 2 μm.

When the CIGS crystal powder 110 is filled in the first evaporation source 105, the chamber 101 may maintain the vacuum state and the substrate fixing part 103 may heat the substrate 10 at a predetermined temperature.

Further, the substrate 10 is heated to uniformly deposit the CIGS crystal powder 100 evaporated from the first evaporation source 105, to be described below, on the surface of the substrate 10.

Then, the CIGS crystal powder 110 is heated by heating the first evaporation source 105 and thus, the CIGS crystal powder 110 can be evaporated (or vaporized) from the first evaporation source 105 (S20).

The CIGS crystal powder 110 evaporated from the first evaporation source 105 may be deposited on the substrate 10 (S30). According to the embodiment, the electrode layer may be first formed on the substrate 10 and the CIGS crystal powder 110 is evaporated and deposited on the electrode layer.

The evaporated CIGS crystal powder 110 forms the CIGS thin film on the substrate 10 and then, the selenization process is performed in order to improve the characteristics of the CIGS thin film (S40).

The selenization process is performed by evaporating the selenium metal powder 120 filled in the second evaporation source 107.

For example, the CIGS thin film is formed on the substrate 10 and the second evaporation source 107 is then heated, such that the selenium metal powder 120 filled in the second evaporation source 107 is evaporated. The selenization process is performed on the CIGS thin film by using the evaporated selenium metal powder 120.

Meanwhile, the selenization process is performed while the CIGS thin film is formed. In other words, the selenium metal powder 120 is evaporated by heating the second evaporation source 107 while evaporating the CIGS crystal powder 110 by heating the first evaporation source 105.

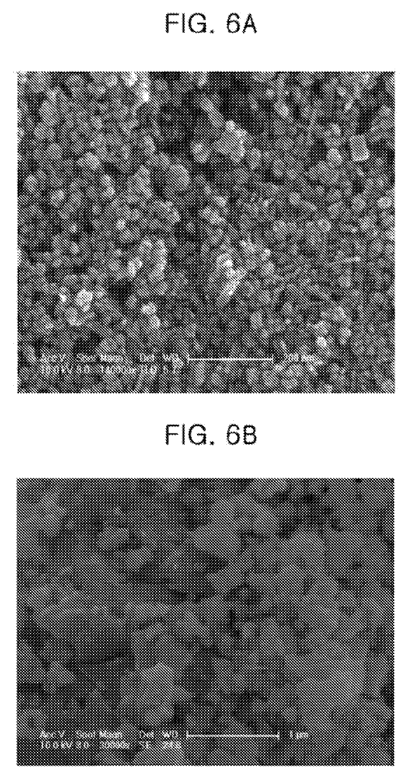

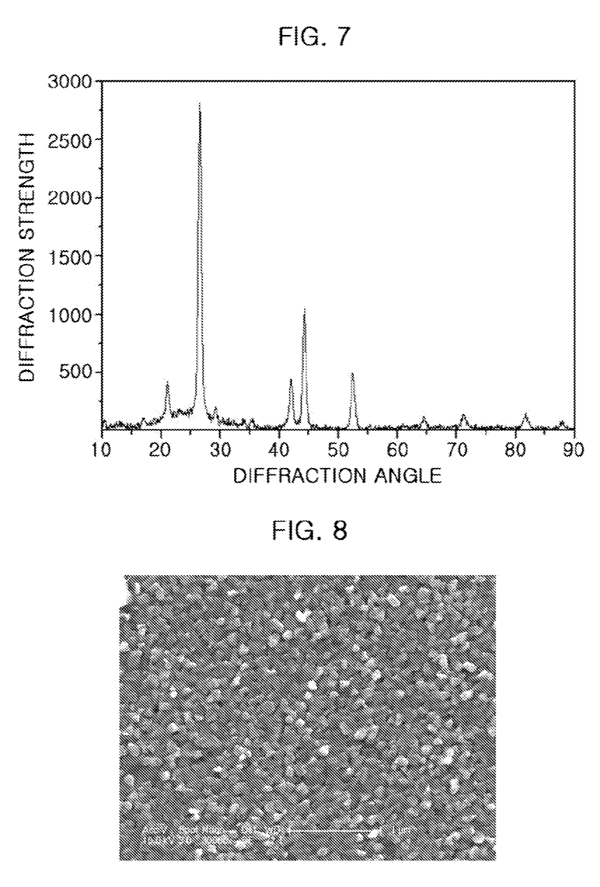

The CIGS thin film completed by performing the selenization process, that is, the thin film type light absorbing layer can be formed at a thickness of approximately 100 nm to 3 μm. As shown in FIGS. 7 and 8, the thin film type light absorbing layer can have the CIGS thin film structure that the crystal particles are dense and the grains are formed well.

The process of forming the thin film type CIGS light absorbing layer in the thin film solar cell by using the method of evaporating the CIGS crystal powder 110 has been described. Hereinafter, the manufacturing method for a thin film solar cell including the process of forming the above-mentioned thin film type light absorbing layer will be described.

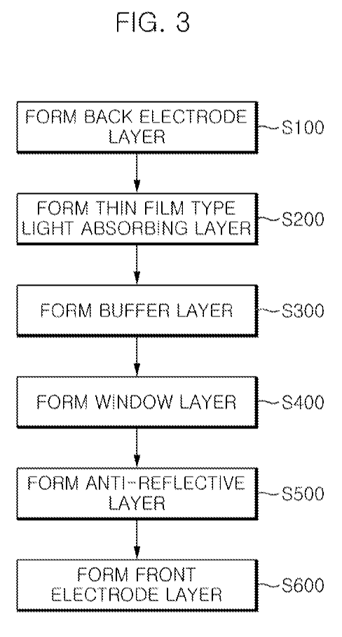

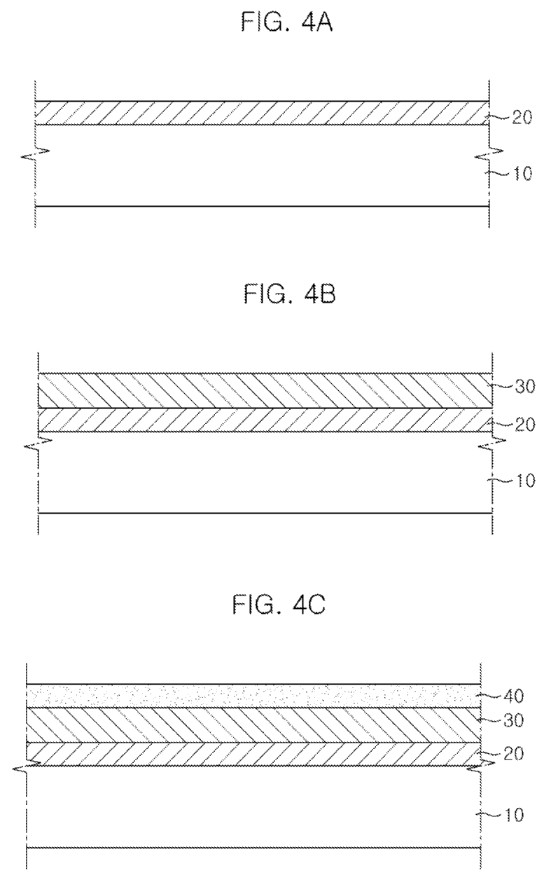

FIG. 3 is a process flow chart of a manufacturing method for a thin film solar cell according to one embodiment of the present invention and FIGS. 4A to 4F are diagrams according to the process flow chart of FIG. 3.

The manufacturing method for a thin film solar cell according to the present embodiment includes forming the thin film type light absorbing layer using the CIGS crystal powder (S200). This was already described in detail with reference to FIGS. 1 and 2 and therefore, the detailed description of the present embodiment will be omitted.

Referring to FIGS. 3 and 4A, the electrode layer, for example, a back electrode layer 20 can be formed on the substrate 10 (S100).

The substrate 10 can be one of a soda ash glass substrate, a stainless metal substrate, and a polymide polymer substrate, as described above. The substrate 10 may be polished and dried with a solution, such as DI water, acetone, ethanol, etc.

The back electrode layer 20 may be formed on one surface of the substrate 10. The back electrode layer 20 may be formed by depositing metal materials such as molybdenum (Mo), etc., on one surface of the substrate 10 using the sputtering deposition method.

For example, the back electrode layer 20 may be formed by the sputtering deposition method that applies sputtering power of approximately 30 to 100 watt to molybdenum in an argon gas chamber at approximately 1 to 10 mTorr.

The back electrode layer 20 may be formed on one surface of the substrate 10 at a thickness of approximately 1 μm.

Referring to FIGS. 3 and 4B, when the back electrode layer 20 is formed on one surface of the substrate 10 and the thin film type light absorbing layer 30 may be formed on the back electrode layer 20 as described with reference to FIGS. 1 and 2 (S200).

The thin film type light absorbing layer 30 may be formed on the back electrode layer 20 by using the evaporation deposition method that evaporates the CIGS crystal powder.

Referring to FIGS. 3 and 4C, when the back electrode layer 20 and the thin film type light absorbing layer 30 are formed on one surface of the substrate 10, the buffer layer 40 may be formed on the thin film type light absorbing layer 30 (S300).

The buffer layer 40 may be formed by depositing a cadmium sulfate (CdS) thin film on the thin film type light absorbing layer 30 by using a chemical deposition method.

For example, the buffer layer 40 may be deposited on the thin film type light absorbing layer 30 by dipping the substrate 10, on which the back electrode layer 20 and the thin film type light absorbing layer 30 are formed, in a mixed solution in which cadmium sulfate (CdSO₄), ammonium hydroxide (NH₄OH), ammonium chloride (NH₄Cl), thiourea (CS(NH₂)₂), and DI water are mixed.

At this time, the buffer layer 40 may be deposited by heating the mixed solution at approximately 70° C. and the buffer layer 40 may be deposited on the thin film type light absorbing layer 30 at a thickness of approximately 50 mm.

Referring to FIGS. 3 and 4D, when the back electrode layer 20, the thin film type light absorbing layer 30, and the buffer layer 40 are formed, a first window layer 51 may be formed on the buffer layer 40 (S400).

The first window layer 51 may be formed by depositing a metal such as zinc oxide (ZnO), etc., on the buffer layer 40 by using an RF sputtering deposition method.

The first window layer 51 may be deposited on the buffer layer 40 at a thickness of approximately 50 mm.

Referring to FIGS. 3 and 4E, when the back electrode layer 20, the thin film type light absorbing layer 30, the buffer layer 40, and the first window layer 51 are formed, a second window layer 55 may be formed on the first window layer 51 (S400).

The second window layer 55 may be formed by depositing zinc oxide (ZnO) doped with aluminum oxide (Al₂O₃) on the first window layer 51 by using the RF sputtering deposition method.

The second window layer 55 may be deposited on the first window layer 51 at a thickness of approximately 500 mm.

In other words, the window layer 50 may include the first window layer 51 and the second window layer 55 may be formed by sequentially depositing a material used as a target, for example, zinc oxide doped with intrinsic zinc oxide or aluminum oxide using the RF sputtering deposition method.

Although not shown in the drawings, it may further include forming an anti-reflective layer (not shown) on the window layer 50 (S500). The anti-reflective layer may be formed by depositing magnesium fluoride (MgF₂) on the window layer 50.

Referring to FIGS. 3 and 4F, when the back electrode layer 20, the thin film type light absorbing layer 30, the buffer layer 40, and the window layer 50 are formed, a front electrode layer 60 may be formed on the window layer 50 (or anti-reflective layer) (S600).

The front electrode layer 60 may be formed by depositing aluminum (Al) on the window layer 50 using the sputtering deposition method.

As a result, the thin film solar cell 1 including the back electrode layer 20, the thin film type light absorbing layer 30, the buffer layer 40, the window layer 50, and the front electrode layer 60, which are formed on one surface of the substrate 10, can be completed.

FIG. 5, which is shown but not described, a graph of analyzing an X ray crystal structure of the CIGS crystal powder that forms the thin film type light absorbing layer and FIGS. 6A and 6B are pictures of crystal particles of CIGS crystal powder taken by electron microscope.

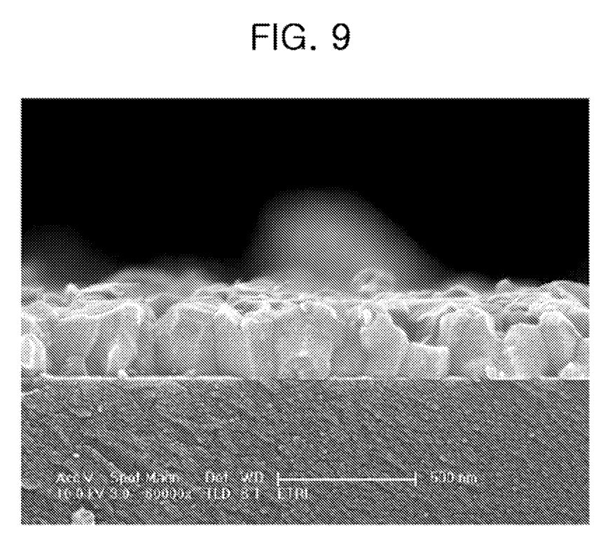

In addition, FIG. 7 is a graph of analyzing an X ray crystal structure of the thin film type light absorbing layer, FIG. 8 is a picture of surface of the thin film type light absorbing layer taken by electron microscope, and FIG. 9 is a picture of cross section of the thin film type light absorbing layer taken by electron microscope.

Although the exemplary embodiments have been described and illustrated in the drawings and the description, this has been described by way of example. Therefore, it will be appreciated to those skilled in the art that various modifications are made and other equivalent embodiments are available. Accordingly, the actual technical protection scope of the present invention must be determined by the spirit of the appended claims.

What is claimed is:

1. A manufacturing method for a thin film type light absorbing layer, comprising:
filling CIGS crystal powder in an evaporation source of a chamber;
simultaneously evaporating the CIGS crystal powder; and
depositing the evaporated CIGS crystal powder on a substrate to form the CIGS thin film.

2. The manufacturing method for a thin film type light absorbing layer according to claim 1, further comprising:
after forming the CIGS thin film, evaporating selenium metal powder and then performing a selenization process on the CIGS thin film.

3. The manufacturing method for a thin film type light absorbing layer according to claim 1, wherein the CIGS crystal powder has a diameter of 10 nm to 2 μm.

4. The manufacturing method for a thin film type light absorbing layer according to claim 1, wherein the CIGS crystal powder has a composition ratio of copper:indium:gallium:selenium of 1:(1−x):x:y, wherein x represents a real number of more than 0 to less than 1 and y represents a real number of 1 to 3.

5. The manufacturing method for a thin film type light absorbing layer according to claim 1, wherein the CIGS thin film is formed on the substrate at a thickness of 100 nm to 3 μm.

6. The manufacturing method for a thin film type light absorbing layer according to claim 1, wherein the simultaneously evaporating the CIGS crystal powder includes:
heating the substrate while maintaining the chamber in a vacuum state; and
evaporating the CIGS crystal powder by heating the evaporation source.

7. The manufacturing method for a thin film type light absorbing layer according to claim 6, wherein the evaporation source is heated at 1000 to 1400°.

8. The manufacturing method for a thin film type light absorbing layer according to claim 1, further comprising:
forming an electrode layer on the substrate prior to forming the CIGS thin film, the CIGS thin film being formed on the electrode layer.

9. A manufacturing method for a thin film solar cell, comprising:
forming a back electrode layer on one surface of the substrate;
forming a thin film type light absorbing layer by evaporating and depositing CIGS crystal powder on the rear electrode layer;
forming a buffer layer on the thin film type light absorbing layer; and
forming a window layer on the buffer layer.

10. The manufacturing method for a thin film solar cell according to claim 9, wherein the forming the thin film type light absorbing layer includes:
filling the CIGS crystal powder in an evaporation source of a chamber;
simultaneously evaporating the CIGS crystal powder; and
depositing the evaporated CIGS crystal powder on the back electrode layer to form the thin film type light absorbing layer.

11. The manufacturing method for a thin film solar cell according to claim 10, further comprising:
after forming the thin film type light absorbing layer, evaporating the selenium metal powder and then performing a selenization process on the thin film type light absorbing layer.

12. The manufacturing method for a thin film type light absorbing layer according to claim 10, wherein the CIGS crystal powder has a diameter of 10 nm to 2 μm.

13. The manufacturing method for a thin film type light absorbing layer according to claim 10, wherein the CIGS crystal powder has a composition ratio of copper:indium:gallium:selenium of 1:(1−x):x:y, wherein x represents a real number of more than 0 to less than 1 and y represents a real number of 1 to 3.

14. The manufacturing method for a thin film type light absorbing layer according to claim 10, wherein the thin film type light absorbing layer is formed on the back electrode layer at a thickness of 100 nm to 3 μm.

15. The manufacturing method for a thin film type light absorbing layer according to claim 9, further comprising forming an anti-reflective layer on the window layer.

16. The manufacturing method for a thin film type light absorbing layer according to claim 9, further comprising forming a front electrode layer on the window layer.

17. A thin film solar cell according, comprising:
a back electrode layer that is formed on one surface of a substrate;
a thin film type light absorbing layer that is formed by evaporating and depositing the CIGS crystal powder on the back electrode layer;
a buffer layer that is formed on the thin film type light absorbing layer, and
a window layer that is formed on the buffer layer.

18. The thin film solar cell according to claim 17, further comprising a front electrode layer formed on the window layer.

19. The thin film solar cell according to claim 17, wherein the substrate is one of soda ash glass substrate, a stainless metal substrate, and a polymide polymer substrate.
